(19) United States
(12) Patent Application Publication
(10) Pub. No.: US 2021/0325495 A1
(43) Pub. Date: Oct. 21, 2021

(54) METHOD AND SYSTEM

(71) Applicant: The University of Melbourne, Victoria (AU)

(72) Inventors: Roger John Ordidge, Victoria (AU); Bradford Armstrong Moffat, Victoria (AU)

(21) Appl. No.: 16/324,506

(22) PCT Filed: Aug. 11, 2017
(86) PCT No.: PCT/AU2017/050858

§ 371 Date: Feb. 8, 2019

(30) Foreign Application Priority Data
Aug. 11, 2016 (AU) 2016903167

(51) Int. Cl. G01R 33/483; G01R 33/46

(52) U.S. Cl. CPC G01R 33/4833; G01R 33/4616

(57) ABSTRACT

A composite pulse sequence for MR systems is described. The pulse sequence involves a plurality of pulses which each individually have a desired rotation (A°, B° etc.) in which the pulses each cause a rotation about respective axes. Slice selection magnetic gradients may be employed to make the component rotations of the composite pulse slice selective. Optionally phase correction (re-phasing) gradients can also be included in the pulse sequence. One or more of the pulses making up the composite pulse are not based on a sinc shaped pulse envelope.

### FIELD OF THE INVENTION

This invention generally relates to Magnetic Resonance Imaging. Embodiments may be particularly advantageous in non-uniform magnetic fields.

### BACKGROUND OF THE INVENTION

Magnetic Resonance Imaging (MRI) exploits the nuclear magnetic resonance (NMR) phenomena by combining NMR with gradient magnetic fields to allow cross-sectional slice-selective excitation of nuclei within a subject under examination. In multi-slice imaging, a pulse-sequence of radio-frequency magnetic fields (RF pulse) and associated magnetic field gradients are used with further two dimensional (2D) encoding of the NMR signals to create a 2D image of a portion of the subject. Each slice has an in-slice resolution of around 0.5 mm to 1 mm and slices are spaced around 2 mm apart. A 3D image of the subject is obtained by combining many slices together.

Ideally, in an MRI system the RF pulse should deliver a target rotation of the nuclear magnetization vector to provide uniform signal strength over the dimensions of the slice. However, in practice the RF field might typically vary by as much as 50% causing loss of both signal strength and alteration of image contrast by producing magnetization rotations that are far away from the target excitation angle. This variation is typically caused by local magnetic and electrical field effects in the subject can lead to spatial inhomogeneity in the local radio-frequency (RF) transverse magnetic field (B1) the nuclei are exposed to. By increasing the static magnetic field strength (B0) an improved signal-to-noise ratio may be obtained along with improved spatial resolution in the images created. However, the above mentioned inhomogeneity in the B1 field is more problematic at B0 fields above 3T and can lead to imaging artefacts which, in the worst case, are manifested as zero signal in some regions of the image. B1 inhomogeneity effects may also occur at low or medium B0 fields, and when inhomogeneous RF coils such as surface coils are used.

In order to address at least some of the drawbacks noted above, the present inventors have developed a composite pulse sequence cause a series of magnetic moment rotations that, in combination, are equivalent to a pulse sequence that would cause a single rotation having a target desired rotation, which is described in PCT/AU2016/050068, also in the name of The University of Melbourne, the contents of which are incorporated herein by reference for all purposes.

The composite RF magnetic field pulse sequence described in that application includes two or more RF magnetic field pulses, which together replace a single conventional RF magnetic field pulse. Preferred embodiments of that invention can provide additional receives signal strength and slices with more even rotation across them, leading to more even contrast across an image. The inventors have also identified that non-slice selective versions of the composite RF magnetic field pulse sequence disclosed in that application could also be utilised in some applications, such as MR spectroscopy and three dimensional MRI. The non-slice selective versions of said pulses exclude the slice selection gradients taught in that application.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF THE INVENTION

The inventors have now made new developments that may advantageously be used in a composite pulse sequence involves a plurality of pulses which each individually have a desired rotation (A°, B° etc.) in which the pulses each cause a rotation about respective axes. Slice selection magnetic gradients may be employed to make the component rotations of the composite pulse slice selective. Optionally phase correction (re-phasing) gradients can also be included in the pulse sequence. In the preferred forms the one or more of the pulses making up the composite pulse are not based on a sinc shaped pulse envelope. Preferably they are shaped in accordance with a windowed, pulse shaping function, where the pulse shaping function does not theoretically correspond a rectangular frequency response, e.g. like a root raised cosine filter, raised cosine filter or the like. Preferably the pulse shaping function theoretically produces a smoothed rectangular frequency response. Two or more of the pulses may have the same pulse shape.

In a first aspect there is provided a method for use in magnetic resonance imaging or spectroscopy, including:
exposing at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field (B0);
   performing a composite rotation includes:
performing a first rotation by:
exposing at least said portion of the subject to a first radio-frequency magnetic field pulse (B1a) excite nuclei within at least a portion subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
   performing a second rotation by:
exposing at least said portion of the subject to a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
   wherein at least one of the first or second radio-frequency magnetic field pulses are generated in the time domain in a manner that corresponds to a non-rectangular frequency response.

In some examples the at least one of the first or second radio-frequency magnetic field pulses are generated in the time domain in a manner that approximates use of finite impulse response filter which corresponds to a non-rectangular frequency response.

In some embodiments the finite impulse response filter comprises a windowing filter and a pulse shaping filter.

Preferably the pulse shaping filter is not a sinc filter.

In some embodiments the pulse shaping filter can be one or more of:

Root raised cosine filter

Raised cosine filter

In some embodiments said pulse(s) are generated in the time domain in a manner that approximates use of finite impulse response filter which corresponds to a rectangular frequency response with smoothed edges.

In another aspect there is provided a method for use in magnetic resonance imaging or spectroscopy, including:
exposing at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field (B0);
   performing a composite rotation includes:
performing a first rotation by:
exposing at least said portion of the subject to a first radio-frequency magnetic field pulse (B1a) excite nuclei within at least a portion subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
   performing a second rotation by:
exposing at least said portion of the subject to a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
wherein at least one of the first or second radio-frequency magnetic field pulses do not approximate a rectangular frequency response.

In some embodiments said pulse(s) are generated in the time domain in a manner that approximates a rectangular frequency response with smoothed edges. For example, in some embodiments magnetic field pulses can be based on a Root raised cosine filter or Raised cosine filter in the time domain.

In other aspects of the present invention, there are provided composite magnetic resonance pulse sequences to be used with a magnetic resonance imaging or spectroscopy system. The pulse sequences may be used by any one of the methods disclosed herein.

In further aspects the present invention further provides MR systems configured to perform any one of the methods disclosed herein.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF THE DRAWINGS

FIG. 1 is a block diagram of a magnetic resonance imaging system;

FIG. 2a is a vector diagram showing the equilibrium net magnetisation from an ensemble of nuclei in a uniform magnetic field B0;

FIG. 2b illustrates a pair of vector diagrams, the leftmost being a three dimensional diagram, and the rightmost being a projection onto the y-z plane, each a first rotation of the net magnetisation when the ensemble of nuclei are excited by a suitable RF magnetic field;

FIG. 2c illustrates a pair of vector diagrams, the leftmost being a three dimensional diagram, and the rightmost being a projection onto the x-z plane, each showing a second rotation of the net magnetisation when the ensemble of nuclei are excited by a suitable RF magnetic field;

FIG. 3 is a plot of an exemplary MRI pulse sequence;

FIG. 4 illustrates the shape of the pulses from an exemplary pulse sequence according to an embodiment.

FIG. 5 illustrates another exemplary MRI pulse sequence.

FIGS. 6A and 6B illustrates a comparison between a pulse sequence according to an embodiment of the present invention (6A), compared to a the equivalent pulse sequence using time limited Sinc pulses (6B).

FIGS. 7A and 7B illustrate a comparison between a pulse second sequence, 7A having an amplitude greater than that of FIG. 6A, compared to the equivalent pulse sequence using time limited Sinc pulses (shown in 7B).

FIGS. 8A and 8B illustrate a comparison between a pulse third sequence, having an RF amplitude more than double that of FIG. 6A, compared to a the equivalent pulse sequence using time limited Sinc pulses (6B).

FIG. 9 illustrates a plot of signal level (as a percentage of peak signal of composite pulse using component Sinc pulses) for a range of flip angles.

FIG. 10 illustrates a plot of signal level for a range of flip angles for two embodiments, one of which has a composite pulse with its component pulses having a non-90 degree phase offset.

FIG. 11 illustrates another embodiment of an MRI pulse sequence according to an aspect of the present invention. This example uses three pulses in two axes of rotation to generate a slice selective 180 degree refocussing pulse, or an inversion pulse when the initial magnetisation starts along the +z axis.

### DETAILED DESCRIPTION OF THE EMBODIMENTS

Turning now to the figures, FIG. 1 shows a highly schematic block diagram of a Magnetic Resonance Imaging (MRI) system 10 including:
a magnetic field producing means 20;
a magnetic field gradient producing means 30;
a radio-frequency magnetic field generating means 40;
an RF receiver 46;
a positioning means 50; and
a control unit 70.

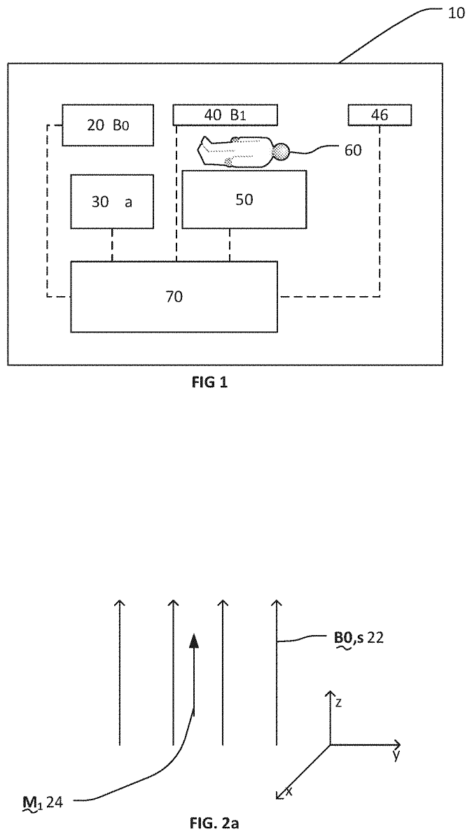

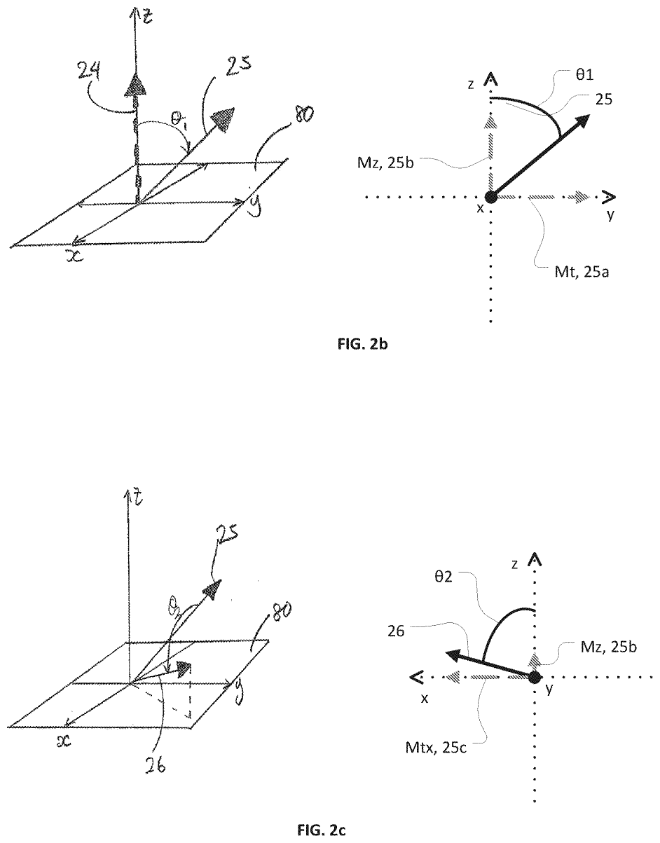

The magnetic field producing means 20 is configured to produce a static uniform magnetic field B0,s, 22 aligned to a longitudinal direction along the z-axis (FIG. 2a). A preferred example of the field producing means 20 is a superconducting magnet system.

The magnetic field gradient producing means 30 is configured to produce a magnetic field gradient G. This can be thought of an additional magnetic field that alters the magnetic field B0,s to produce a modified magnetic field B0, 22. The gradient is not strong enough to vary the direction of the field, so B0 is always parallel with B0,s in the longitudinal axis. Therefore it suffices to define B0 in terms of the component in the longitudinal direction and it is unnecessary to refer to it as a vector quantity. It will therefore be referred to as a scalar quantity B0 without loss of generality. As will be discussed further below, the gradient is used for slice selection, but could be omitted if spectroscopy or three dimensional MRI is being performed.

The radio-frequency (RF) magnetic field generating means 40 is configured to produce transversely oriented RF magnetic fields B1a and B1b, i.e. oriented such that they lie in the x-y plane, that oscillate at a radio-frequency corresponding to the Larmor frequency of a nuclei of interest for MRI (typically protons or carbon-13) exposed to the magnetic field B0. The RF magnetic fields may be linearly or circularly polarised depending on the type of RF magnetic field generating means 40 used and have a phase defined by the operator.

The positioning means 50 is for positioning at least part of a subject 60 in the magnetic field B0.

The system also includes a RF receiver 46, such as RF receiver coils, for receiving an MRI signal. In some embodiments, the RF receiver is part of the RF magnetic field generating means 40. The RF receiver is typically only sensitive to RF magnetic fields oriented in the transverse plane.

In some embodiments, the system 10 includes a control unit 70. Control unit 70 is communicatively coupled with the other components (20, 30, 40, 50) of the system 10. Control unit 70 may include a storage means 72 for storing instructions that determine how the control unit 70 controls the other components (20, 30, 40, 50). Instructions include programs for generating MRI pulse sequences that vary the RF magnetic fields B1 and the magnetic field gradient G to selectively excite nuclei in a cross-sectional slice of the subject exposed to the magnetic field B0. By varying the gradients over two dimensions in k-space, the MRI signals can be spatially encoded to produce a 2D raw image (phase encoding, frequency encoding). Using known Fourier transform MRI techniques, the 2D raw image can be converted or transformed into a 2D image of a cross-sectional slice of the subject. Careful selection of pulse sequence parameters can be used to improve image contrast between various compounds or materials within the subject. By taking many 2D images a 3D image of the subject can be obtained.

The magnetic field producing means 20 may either be controlled by the control unit 70 or it may be persistently producing field B0 (as is usually the case for a superconducting magnet system). The magnetic field producing means 20 and magnetic field gradient producing means may also be in communication with the control unit 70 such that the control unit can monitor their status and/or functionality. For example, the control unit 70 may monitor whether the correct magnetic field strength is being produced, either directly through measuring the proton frequency of the signal from water or indirectly by monitoring an electrical characteristic of the field producing means 20 such as power output.

The subject 60 contains an ensemble of nuclei each with a magnetic moment. When at least a portion of the subject 60 (therefore the ensemble of nuclei within the portion) is exposed to the magnetic field B0 it is considered that, statistically, a greater proportion of the nuclei's magnetic moments become aligned with the magnetic field B0. The time-averaged magnetisation of the portion exposed to the magnetic field B0 is, at equilibrium, described by a net magnetisation vector M, 24 parallel to the direction of the magnetic field B0 (FIG. 2a). At the start of an MRI pulse sequence, the magnetisation M is considered to be at equilibrium and oriented as shown in FIG. 2a.

As will be appreciated by the person skilled in the art, exposure of a subject to a magnetic field is not intended to be limited to mean exposure of a surface of the subject, or the near sub-surface, and is intended to include exposing the nuclei within and throughout the subject to said magnetic field. The use of the term is also intended to include the situation where the MRI system has a persistent magnetic field B0 and the subject is introduced into the field.

Rotation of Magnetisation Vector by RF Magnetic Fields

As is known in the art, a transverse RF magnetic field (B1) that is orthogonal to the main magnetic field B0 is typically used to cause rotation of the net magnetisation M, 24 away from the longitudinal axis (z-axis) so that a component of magnetization is created in the transverse plane.

As illustrated in FIGS. 2b and 2b, in an embodiment of the invention, an MRI sequence with two RF oscillating magnetic fields (B1a and B1b) is used in combination to rotate the magnetisation vector M from its initial alignment in the z-direction away by a desired angle.

FIG. 2b shows in its leftmost figure a three dimensional representation of a magnetisation M, and in its rightmost figure a projection of this rotation onto the y-z plane, to aid visualisation. In this example, the first RF magnetic field (B1a) excites the nuclei and causes a first rotation of the magnetisation M about a first axis (which is defined as the x-axis) by a first angle (01 equal to A°) towards the y-axis and therefore towards the transverse plane 80. As the magnetisation M is rotated away from its original equilibrium orientation 24 aligned with the z-axis, the rotated magnetization 25 can be considered to consist of a transverse vector component (Mt, 25a) in the x-y plane 80 and a residual vector component (z-component) aligned along the z-axis (Mz, 25b). The z-component Mz may be parallel or anti-parallel to the z-axis depending on the magnitude of the first angle θ1. As the ensemble is still exposed to the magnetic field B0, the transverse component Mt (and therefore the rotated magnetisation, M) precesses about the z-axis at the Larmor frequency. The magnetisation vectors shown in the drawings are drawn in the rotating frame of reference rotating at the Larmor frequency.

The desired first angle of rotation θ1 can be set by choosing an appropriate combination of duration and amplitude of a pulsed RF magnetic field B1a. As noted above, parts of the subject being scanned may affect the local strength of the RF magnetic fields (B1) at particular locations (spatial inhomogeneity) and cause the corresponding rotation angle at said locations to also be affected. This may result in up to a 50% variation in the actual rotation angle compared to the set angle, i.e. for a desired 90° rotation angle, this could result in an actual rotation between 45° and 135°.

As shown in FIG. 2c, a second RF magnetic field (B1b) 9 is used to excite the ensemble of nuclei to induce a second rotation of the rotated magnetisation M in orientation 25 about a second axis, in this example the y-axis (therefore orthogonal to the first axis), by a second angle (02) towards the transverse plane 80 to a second orientation 26.

The second rotation can be considered as only rotating the residual component of magnetization Mz 25b towards the transverse plane 80 as the transverse component Mt 25a is aligned with the y-axis. Notably, if the effect of the first rotation was to rotate the magnetisation by 90° into the transverse plane 80 then there is no further rotation by the second RF magnetic field.

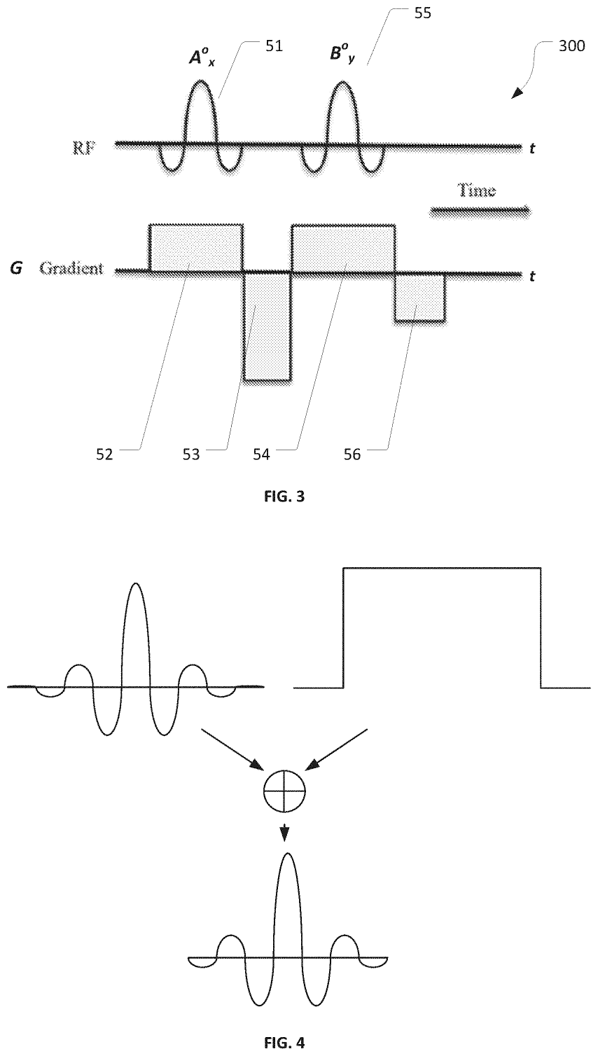

The second angle θ2 can be selected in the same manner as the first angle. Importantly, the spatial inhomogeneity of the first RF magnetic field does not vary greatly with direction of the applied RF field and therefore will have the same effect on the second RF magnetic field B1b and therefore the corresponding rotation angle FIG. 3 illustrates an exemplary slice selective composite RF pulse according to an embodiment of the present invention.

The pulse sequence 300 of FIG. 3 generally includes two RF magnetic field pulses with a phase offset of 90° (i.e. which cause rotation of the net magnetisation about orthogonal axes) and with a pulse amplitude A:B of 1:1, (i.e. the rotation angle of the first pulse is equal to that of the second). In more detail the pulse sequence includes:

a first rotation generated by first RF pulse 51 (B1a), having an amplitude to cause a desired rotation of A° about the x axis. The first rotation is slice selective and thus includes a corresponding first magnetic field gradient 52;

a second rotation, generated by a second RF pulse 55 (B1b) having an amplitude to cause a desired rotation of B° about the y axis. Again the second rotation is slice selective and thus includes a corresponding second magnetic field gradient 54; and

one or more phase adjustments; in this case being, a first re-phasing gradient 53 and a second re-phasing magnetic field gradient 56.

In this example the gradients (52, 54) applied at the time of the B1a and B1b fields have the same amplitude and B1a and B1b overlap in frequencies covered, the same selected slice of the ensemble of nuclei in the subject is excited by both B1a and B1b.

As will be seen, FIG. 5 shows an alternative approach in which the slice selection gradients provide a magnetic field that changes magnitude in opposite directions, that is one of the slice selection gradients has a positive gradient and the other a negative gradient. In this example the second rotation angle B°x is twice that of the first angle A°x. This could be achieved if the pulse length of B1b is twice that of Bia, or the amplitude of B1b is doubled that of Bia, or a suitable combination of pulse length and amplitude adjustment is used. If duration modifications are used, corresponding changes to the slice selection gradients should also be made to ensure that an identical slice is selected. In other embodiments, B1a and B1b are either identical or any other desirable ratio.

In practical embodiments, the RF magnetic fields are limited in time, commonly referred to as RF pulses. However unlike embodiments disclosed in PCT/AU2016/050068 the RF magnetic field is not modulated as a time-limited sinc function.

As will be appreciated by those skilled in the art, conventionally a Sinc shaped RF pulse (truncated by a windowing function) is used to attempt to approximate rectangular function in the frequency domain.

The present inventors have determined that better resistance to B1 non-uniformity may be achieved seeking to generate a slice that is non-rectangular in the frequency domain. In one form the desired slice shape theoretically produced by each RF pulse is generally rectangular but has rounded edges. In one form each edge of the slice profile is smoothed according to a smoothing function. For example with a half-cosine shape raised so that it smoothly takes the edge of the desired slice profile from zero to the maximum of the central Rect(t) function on the rising edge of the slice and from the end of the Rect(t) function, smoothly takes the edge back to zero.

In some forms the RF magnetic field is modulated as a pulse shaping time limited function with a lower interference between neighbouring slices (i.e. lower than an equivalent windowed Sinc function). Thus in the time domain either one of both of the RF Magnetic field pulses B1a and B1b can be considered to be defined by a finite impulse filter which is equivalent to combination of a windowing function and a pulse shaping function that is not a sinc function. Instead it may be another function such as such as a root raised cosine filter or raised cosine filter. The windowing function could be a square filter, hamming window or the like.

In some embodiments, when compared with a sinc-function based pulse shape, the pulse used has fewer high frequency components in the time domain. This means that, in the time domain, the components further away from the centre of the pulse are smaller. As a result the pulse can be shortened in time, with smaller consequences for the slice profile compared to a sinc function-based pulse.

Because Sinc-function based RF pulses have sharp edges, they necessitate larger high frequency components in the time domain, which are more sensitive to truncation. Shorter RF pulses improve the performance of the pulse sequence when imaging MR signal which is off-resonance due to non-uniformity of the main magnetic field.

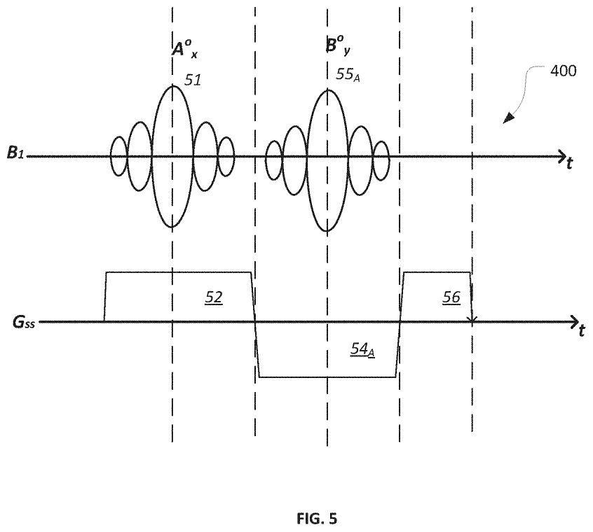

FIG. 4 illustrates the shape of the pulses in the sequence of FIG. 3. The pulse shape is defined by two elements, a pulse shaping filter 390, and a windowing filter 392. In the preferred feature the pulse shaping filter 390 is a root raised cosine filter, and the windowing function 392 is a square filter. When combined the filter shape 394 is a FIR filter which behaves as the pulse shaping filter (e.g. root raised cosine filter) within the bounds of the windowing filter 392. The theoretical frequency domain pulse is a rectangular function with some roll-off providing a smoothed edges. In the example of FIG. 3, both pulses have the same shapes, but different pulse shapes could be used.

FIG. 5 illustrates another exemplary MRI pulse sequence. This differs from the previous embodiment in that instead of applying a re-phasing gradient (53 in FIG. 3) between the two slice selective rotations, the second gradient selected for the second slice selective rotation is arranged to perform the re-phasing role as described below.

This MRI pulse sequence 400 begins with a first radio-frequency magnetic field pulse (51) and a corresponding first magnetic field gradient 52 that are used to excite nuclei within a part of a subject to perform a first slice-selective rotation. As noted above, this first radio-frequency magnetic field pulse rotates a net magnetisation vector about a first axis (e.g. the x axis) such that a portion of the magnetisation now lies in along the y axis. As with the previous example the first slice selection gradient 52 is a magnetic field that has a magnitude that increases along direction that is transverse to the slice being imaged. For convenience this is deemed to be a positive gradient.

Next a second radio-frequency magnetic field pulse (55A) and corresponding second magnetic field gradient 54A is used to cause a second slice-selective rotation. As with the previous embodiment this pulse and slice selection gradient cooperate to rotate the net magnetisation about a second axis (the y axis in this example). Where this embodiment differs from the previous embodiment, is that the second slice selection magnetic field gradient 54A has a negative gradient compared to the first slice selection gradient 52. That is, the magnetic field caused by the second slice selection gradient 54A decreases along the direction in which the first slice selection gradient 52 increases. This means that as well as enabling slice selection, the gradient 54A causes at least partial re-phasing of the magnetisation vectors that were de-phased by the first slice selective rotation process.

As will be appreciated the first and second positive and negative gradients will need to be created so that the slices formed by each gradient are in registration with each other. This may require the second RF pulse to have a negative frequency offset applied to so that the slice centres align along direction of the B0 field. This allows slices offset from the centre of the magnet to be excited.

Finally, the pulse sequence 400 includes final re-phasing magnetic field gradient 56 to correct de-phasing of the magnetisation vectors within the ensemble that are a result of the second slice-selective rotation. Final re-phrasing magnetic field gradient 56 in this case consists of a positive gradient of approximately half the duration of the gradient applied in the previous slice selection gradient segment but equal size.

All individual pulses (i.e. the component pulses of the exemplary composite pulses) are again the same as each other, and are defined as illustrated in FIG. 4. FIG. 4 illustrates the shape of the pulse. The pulse shape is defined by two elements, a pulse shaping filter 390, and a windowing filter 392. In the preferred feature the pulse shaping filter 390 is a root raised cosine filter, and the windowing function 392 is a square filter.

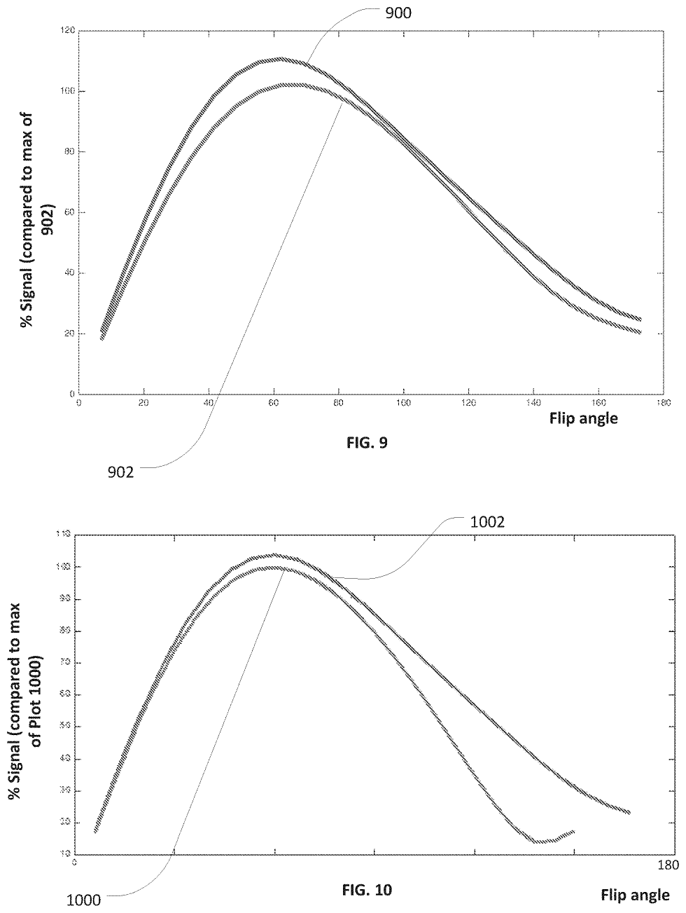

Also in the present example, the first and second pulses are applied 90° out of phase with each other, making their axes of rotation orthogonal. However, in some embodiments other relative phases may be selected to optimise signal level, see for example FIG. 10.

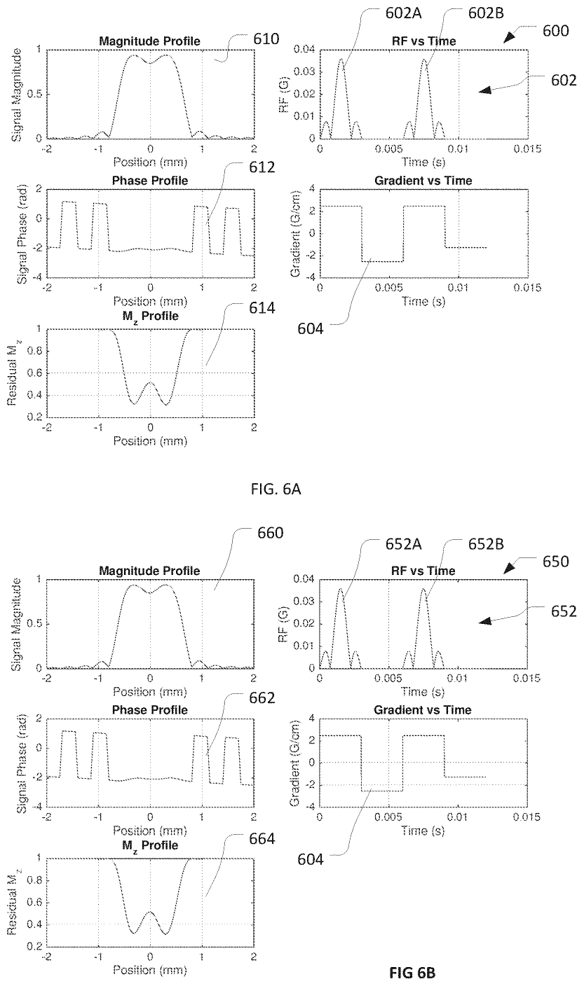

FIGS. 6A and 6B illustrates a comparison between a pulse sequence according to an embodiment of the present invention (FIG. 6A), compared to a pulse sequence using time limited Sinc pulses (FIG. 6B). The pulse sequence according to the present invention is illustrated in FIG. 6A. The pulse sequence 600 seeks to produce two 40 degree rotations, and hence includes two pulses 602A and 602B, comprised of time limited RRC pulses with a roll off factor of 0.5, and having a duration of 0.0035 sec and a peak field of 0.036G. They are made slice selective by the application of corresponding portions of the gradient 604.

FIG. 6B illustrates an equivalent pulse sequence comprised of time limited sinc pulses. The sinc pulse sequence 650 includes two pulses 652A and 652B, comprised of time limited sinc pulses of 0.0035 sec duration and a peak field of 0.036G. They are made slice selective by the application of corresponding portions of the same gradient 604.

The remaining panels of FIGS. 6A and 6B show:
The slice shape, represented by the received signal magnitude for each slice, 610 for the RRC pulse sequence, and 660 for the Sinc pulse sequence.
The phase profile of each pulse, 612 for the RRC pulse sequence, and 662 for the Sinc pulse sequence.
The residual Z magnetisation Mz during the pulse across the slice, 614 for the RRC pulse sequence, and 664 for the Sinc pulse sequence.

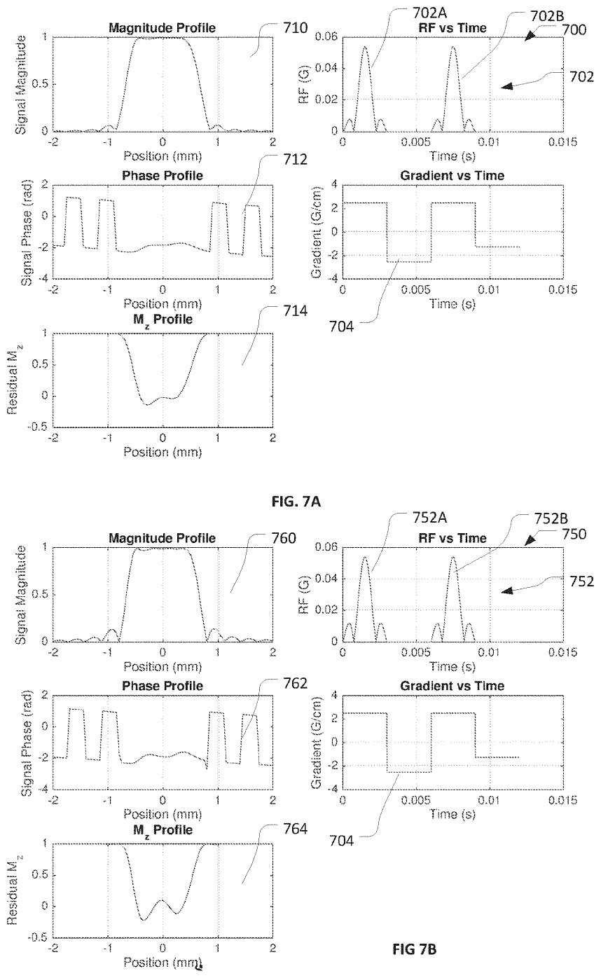

FIGS. 7A and 7B illustrate a similar comparison to that of FIGS. 6A and 6B, except that the pulse sequences are have approximately 1.5 times the field strength of FIG. 6. The pulse sequence according to an embodiment of the present invention is illustrated in FIG. 7A. The pulse sequence 700 seeks to produce two 60 degree rotations, and hence includes two pulses 702A and 702B, comprised of time limited RRC pulses (0.5 roll off factor) of 0.0035 sec duration and a peak field of around 0.054G. They are made slice selective by the application of corresponding portions of the gradient 704. FIG. 7B illustrates an equivalent pulse sequence comprised of time limited sinc pulses. The sinc pulse sequence 750 includes two pulses 752A and 752B, comprised of time limited sinc pulses of 0.0035 sec duration and a peak field of 0.054G. They are made slice selective by the application of corresponding portions of the same gradient 704.

The remaining panels of FIGS. 7A and 7B show:
The slice shape, represented by the received signal magnitude for each slice, 710 for the RRC pulse sequence, and 760 for the Sinc pulse sequence.
The phase profile of each pulse, 712 for the RRC pulse sequence, and 762 for the Sinc pulse sequence.
The residual Z magnetisation Mz during the pulse across the slice, 714 for the RRC pulse sequence, and 764 for the Sinc pulse sequence.

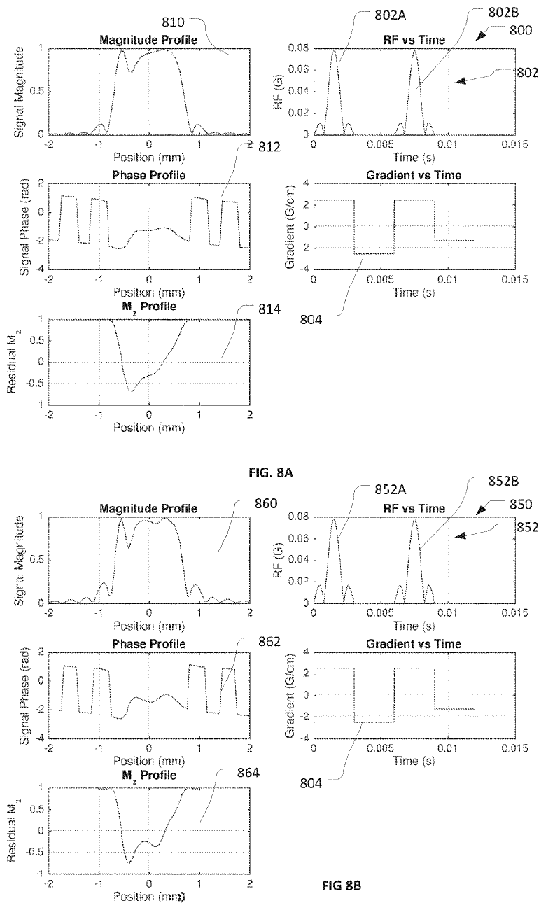

FIGS. 8A and 8B illustrate a similar comparison to that of FIGS. 6A and 6B, except that the pulse sequences have slightly more than twice the field strength and seek to produce two 90 degree rotations. The pulse sequence according to an embodiment of the present invention is illustrated FIG. 8A. The pulse sequence 800 includes two pulses 802A and 802B, comprised of time limited RRC pulses (0.5 roll off factor) of 0.0035 sec duration and a peak field of 0.078G. They are made slice selective by the application of corresponding portions of the gradient 804. FIG. 8B illustrates an equivalent pulse sequence comprised of time limited sinc pulses. The sinc pulse sequence 850 includes two pulses 852A and 852B, comprised of time limited sinc pulses of 0.0035 sec duration and a peak field of 0.078G. They are made slice selective by the application of corresponding portions of the same gradient 804.

The remaining panels of FIGS. 8A and 8B show:
The slice shape, represented by the received signal magnitude for each slice, 810 for the RRC pulse sequence, and 860 for the Sinc pulse sequence.
The phase profile of each pulse, 812 for the RRC pulse sequence, and 862 for the Sinc pulse sequence.
The residual Z magnetisation Mz during the pulse across the slice, 814 for the RRC pulse sequence, and 864 for the Sinc pulse sequence.

As can be seen from comparing the plots, the slices defined by the RRC pulse sequence is better defined and has a more uniform signal across its width. In particular as the pulse field increases the asymmetry in the sinc pulse sequence appears to increase faster than the present inventive embodiment.

FIG. 9 illustrates a plot of signal level (as a percentage of peak signal of composite pulse using component Sinc pulses) for a range of flip angles. The top plot 900, represents a simulation of the received signal a composite pulse according to an embodiment of the present invention including using two equal rotation pulses that were shaped using a root raised cosine filter. The lower plot 902, represents a simulation of the received signal a composite pulse including using two equal rotation pulses that were shaped using a sinc filter. As can be seen the received signal level of the inventive pulse is higher than that of the composite pulse based on the sinc filter over for all flip angles.

FIG. 10 illustrates a plot similar to FIG. 9, however, it compares the received signal level from a composite pulse of an embodiment of the present invention (1000) which uses component root raised cosine filter pulses that have a phase offset between them of 90 degrees, for a range of flip angles; to the received signal level (1002) of a second composite pulse of another embodiment of the present invention which also uses component root raised cosine filter pulses, but which have a phase offset between them of 108 degrees. The received signal level is expressed as a percentage of the peak received signal of plot 1000.

As can be seen the received signal level of the embodiment where the first and second pulses are applied 90° out of phase with each other produces a lower received signal across the range of RF amplitudes. In this example the use of a phase offset between the component pulses of the composite pulse of 108 degrees, gives a greater amplitude signal and a larger amplitude width (measured at 50% of max signal).

In other embodiments different phase angles could be used. For example in some embodiments the phase angle could be within any one or more of the following angular ranges (including end points):

60 degrees or less,

61 to 65 degrees;

66 to 70 degrees;

71 to 75 degrees;

76 to 80 degrees;

81 to 85 degrees;

86 to 90 degrees;

91 to 95 degrees;

96 to 100 degrees;

101 to 105 degrees;

106 to 110 degrees;

111 to 115 degrees;

116 to 120 degrees;

120 degrees or more;

60 to 70 degrees;

70 to 80 degrees;

80 to 90 degrees;

90 to 100 degrees;

100 to 110 degrees;

110 to 120 degrees.

65 to 115 degrees;

Greater than 90 degrees;

Less than 90 degrees;

70 to 110 degrees;

90 to 110 degrees.

The optimal relative phase difference may be dependent on the shape of the pulses making up the composite pulse. The optimal phase offset between components of a composite pulse could be determined empirically, by simulation or the like.

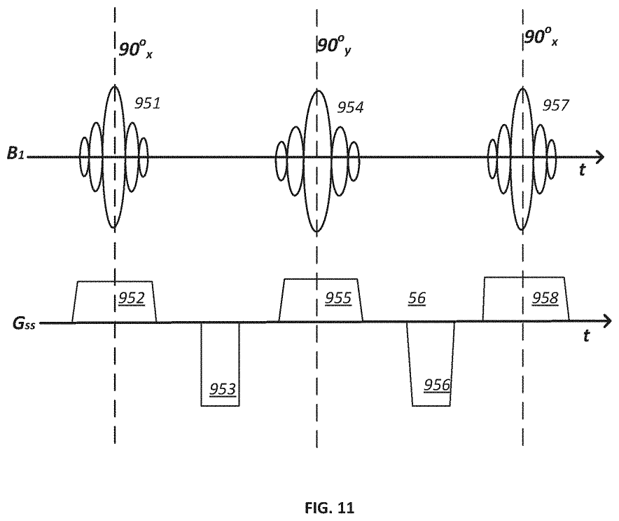

FIG. 11, illustrates a pulse sequence for achieving a rotation equivalent to a slice-selective 180 degree refocussing pulse or an inversion pulse. Compared to the previous embodiments it includes a further radio-frequency magnetic field pulse (B1cᵢ) to rotate the net magnetisation about a further axis by a further angle C°i. The “further axis” in this case is x-axis and thus matches the first axis of rotation.

In summary this example applies three successive 90 degree rotations and each rotation is applied orthogonally to each previous rotation. In FIG. 11 the top plot represents the RF magnetic field pulses B1, which in this example are shaped RRC pulses (but may be another non-sinc shaped pulse). The lower plot illustrates applied magnetic field gradients.

For the refocussing pulse the magnetization is assumed to start in the x-y plane and must be “flipped-over” along an axis.

The pulse sequence illustrated in FIG. 11 begins with a slice selective rotation generated by the application of a first RF magnetic field pulse 951 and an associated corresponding magnetic field gradient 952. The magnetic field gradient has a magnitude that increases along a direction transverse to a slice being selected. The slice selective rotation 951 is configured to generate a 90 degree rotation (i.e. has a desired rotation of 90 degrees) in the positive direction about the x axis. Next a re-phasing gradient 953 is applied with a reversed gradient direction to the first slice selection magnetic field gradient 952. The re-focussing magnetic field gradient 953 is generated to re-phase the de-phased gradients generated by the first slice selective rotation.

Then a second slice selective rotation is generated by the application of a second RF magnetic field pulse 954 and an associated corresponding second magnetic field gradient 955. The magnetic field gradient has a magnitude that increases along a direction transverse to a slice being selected. The slice selective rotation 954 is configured to generate a 90 degree rotation in the positive direction about the Y axis.

Next a re-phasing gradient 956 is applied with a reversed gradient direction to the second slice selection magnetic field gradient 955. The re-focussing magnetic field gradient 956 is generated to re-phase the de-phased gradients generated by the first slice selective rotation.

Then a third slice selective rotation is generated by the application of a third RF magnetic field pulse 957 and an associated corresponding third magnetic field gradient 958. The magnetic field gradient has a magnitude that increases along a direction transverse to a slice being selected. The third slice selective rotation 957 is also configured to generate a 90 degree rotation in the positive direction about the x-axis. In this example the third slice selective rotation is generated by application of an RF magnetic pulse and gradient field that are essentially the same as those used in the first slice selective rotation.

As can be seen the associated gradient waveform is symmetric, just like in the standard 180° refocusing pulse; the extra re-phasing gradient lobe not being required since the magnetization starts in the x-y plane and not along the z-axis. Note all three pulses are 90° and the signal excited by the first pulse effectively experiences zero phase from the subsequent four gradient lobes. Each of the RF magnetic field pulses may have the same or different pulse shapes. At least one (or more) of the pulses making up the pulse sequence is not based on a sinc shaped pulse envelope. Preferably they are shaped in accordance with a windowed, pulse shaping function, where the pulse shaping function does not theoretically correspond a rectangular frequency response, e.g. such as a root raised cosine filter, raised cosine filter or the like. Preferably the pulse shaping function theoretically produces a smoothed rectangular frequency response.

As will be appreciated, any of the pulse sequences described or exemplified in PCT/AU2016/050068 and PCT/AU2017/050810 (the contents of which are incorporated herein by reference) could be modified to use at least one non-sinc pulse shape, as described herein.

1. A method for use in magnetic resonance imaging or spectroscopy, including:
exposing at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field (B0);
performing a composite rotation includes:
performing a first rotation by:
exposing at least said portion of the subject to a first radio-frequency magnetic field pulse (B1a) excite nuclei within at least a portion subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
performing a second rotation by:
exposing at least said portion of the subject to a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
wherein at least one of the first or second radio-frequency magnetic field pulses are generated in the time domain in a manner that corresponds to a non-rectangular frequency response.

2. A method as claimed in claim 1 wherein said at least one of the first or second radio-frequency magnetic field pulses are generated in the time domain in a manner that approximates use of finite impulse response filter which corresponds to a non-rectangular frequency response.

3. A method as claimed in claim 2 wherein the finite impulse response filter comprises a windowing filter and a pulse shaping filter.

4. A method as claimed in claim 3 wherein the pulse shaping filter is not a sinc filter.

5. A method as claimed in claim 3 wherein the pulse shaping filter is one or more of:
Root raised cosine filter; and
Raised cosine filter.

6. A method as claimed in claim 1 wherein the said pulse(s) are generated in the time domain in a manner that approximates use of finite impulse response filter which corresponds to a rectangular frequency response with smoothed edges.

7. The method of claim 1, wherein the first axis and the second axis lie in a transverse plane orthogonal to the magnetic field (B0).

8. The method of claim 1 wherein the first axis and second axis are orthogonal to each other in a rotating frame of reference about the longitudinal direction

9. The method of claim 1, wherein A° and B° are equal.

10. The method of claim 1, wherein A° is less than or greater than B°.

11. (canceled)

12. (canceled)

13. The method as claimed in claim 1, which further includes applying a first slice selection gradient, comprising a magnetic field gradient corresponding to the first radio-frequency magnetic field pulse (B1a) to make said first radio-frequency magnetic field pulse slice selective.

14. The method as claimed in claim 13 which further includes applying a second slice selection gradient comprising a magnetic field gradient corresponding to the second radio-frequency magnetic field pulse (B1b) to make the second radio-frequency magnetic field pulse slice selective.

15. The method as claimed in claim 1, wherein performing each composite rotation further includes exposing at least said portion of the subject to at least one phase adjustment magnetic field gradient to adjust the relative phasing of the magnetisation vectors within the ensemble, either before, during or after one or more of the first or second rotations.

16. The method of claim 15 wherein a re-phasing gradient is applied after the first rotation.

17. The method of claim 16 wherein the second slice selection gradient comprises a re-phasing gradient that is configured to adjust the relative phasing of the magnetisation vectors within the ensemble after the first rotation.

18. The method of claim 16 wherein a re-phasing gradient is applied after the second rotation.

19. The method of claim 1 wherein performing the composite rotation includes:
exposing at least said portion of the subject to a further radio-frequency magnetic field pulse (B1cᵢ) and to excite nuclei within the portion of the subject, the further radio-frequency magnetic field pulse being configured to rotate the net magnetisation about a further axis by a further angle C°ᵢ.

20. (canceled)

21. The method of claim 1 wherein the first axis and second axis are not orthogonal to each other in a rotating frame of reference about the longitudinal direction.

22. The method of claim 21 wherein the first axis and second axis are not offset by more than 90 degrees to each other in the rotating frame of reference.

23. A magnetic resonance system including:
magnetic field producing means for producing a magnetic field (B0);
radio-frequency magnetic field generating means configured to produce radio-frequency magnetic fields (B1a and B1b); and
positioning means for positioning at least part of a subject to be exposed to the effective magnetic field;
the system being configured to perform a method as claimed in claim 1.

24. (canceled)
